(19) United States
(12) Patent Application Publication
(10) Pub. No.: US 2007/0012948 A1
(43) Pub. Date: Jan. 18, 2007

(54) Combined APD / PIN InGaAs photodetector with microlens structure and method of manufacture

(76) Inventors: J. Christopher Dries, Skillman, NJ (US); Michael J. Lange, Newtown, PA (US)

Correspondence Address: Michael R. Friscia;McCarter & English, LLP, Four Gateway Center, 100 Mulberry Street, Newark, NJ, 07102, US

(21) Appl. No.: 11/182,493

(22) Filed: Jul. 15, 2005

(51) Int. Cl. H01L 21/00; H01L 31/072

(52) U.S. Cl. 257/186; 438/48; 257/432; 438/65; 257/438

(57) ABSTRACT

An InGaAs photodetector is provided having an avalanche photodiode (APD), a p-intrinsic-n (PIN) photodiode, and a microlens structure that provides high optical fill factors for both the APD and the PIN photodiodes. The photodetector can be used for both ranging and imaging applications, can be formed as a single pixel, and multiple pixels can be fabricated to form a focal plane array. A method of fabricating the photodiode is also provided.

### BACKGROUND OF THE INVENTION

1. Field of the Invention

The present invention relates to Indium Gallium Arsenide (InGaAs) photodetectors. More specifically, the present invention relates to a photodetector having an avalanche photodiode (APD), a p-intrinsic-n (PIN) photodiode, a microlens structure, and a method of manufacture therefor.

2. Related Art

InGaAs photodetectors are frequently used in a number of optoelectronic systems, and serve a number of functions. For example, in telecommunication applications, InGaAs photodetectors provide for high-speed data communications using fiber-optic media, including optical switching and multiplexing functions. Additionally, InGaAs photodetectors are often used in free-space optical communication systems, for tracking and reception functions.

Avalanche photodiodes (APDs) and p-intrinsic-n (PIN) photodiodes represent two types of InGaAs photodetectors that are utilized in optical imaging and communications systems. APDs are particularly well-suited to high-speed, high-bandwidth data transmission applications, and frequently include a guard ring disposed annularly about the photosensitive region of the photodiode to prevent premature breakdown at the edge of the device. PIN photodiodes are often employed in lower dark current applications that require slower switching speeds, including beam tracking for free-space optical communication systems. Both APDs and PIN photodiodes can be formed in a single device, such as the combined APD/PIN photodetector disclosed in U.S. Pat. No. 6,555,890 to Dries, et al., the entire disclosure of which is expressly incorporated herein by reference.

A particular problem with APDs and PIN photodiodes is the inability to achieve high (e.g., near 100 percent) optical fill factors. In such devices, not all incident light hitting the device fills the photosensitive regions of the device, thus leading to reduced sensitivity and efficiency. In such situations, not all charge carriers formed in the active layer of the device can be detected by the photodiodes. Thus, there is a need to increase optical fill factors of such devices to provide higher sensitivities.

Accordingly, what would be desirable, but has not heretofore been developed, is a photodetector having an APD photodiode, a PIN photodiode, and a microlens structure formed in the same device, wherein high (e.g., 100 percent) optical fill factors are provided for both the APD and the PIN photodiodes.

### SUMMARY OF THE INVENTION

The present invention relates to an InGaAs photodetector having an avalanche photodiode (APD) and a p-intrinsic-n (PIN) photodiode formed in the same device, wherein high (e.g., 100 percent) optical fill factors are provided for both the APD and the PIN photodiodes. The photodetector can be formed as a single pixel, and multiple pixels can be provided to form a focal plane array. The APD photodiode is formed in a central region of the device, and could optionally be provided with a floating guard ring. The PIN photodiode could be formed in any desired geometry and positioned at any desired location in within the pixel region and outside of the central region occupied by the APD. A microlens structure is provided and focuses light on the APD to achieve a high (e.g., 100 percent) optical fill factor. During PIN photodiode operation, the APD can be open-circuited and the PIN photodiode detects light over the entire pixel region, including the space occupied by the APD. During APD photodiode operation, the APD can be reverse biased, and the APD photodiode detects light focused on the APD by the microlens structure. The photodetector can be utilized for combined ranging and intensity (imaging) applications.

In another embodiment of the present invention, a focal plane array having a plurality of photodetectors is provided, each of the photodetectors having an APD photodiode, a PIN photodiode, and a microlens structure for focusing light on the APD. A common cathode is provided along the perimeter of the focal plane array, and each of the APD and PIN photodiodes of the photodetectors can be independently biased. The microlenses can be provided on the substrate of the focal plane array. The focal plane array can be hybridized with a suitable read-out integrated circuit (ROIC), and can be utilized in ranging and imaging applications.

The present invention also relates to a method of fabricating an InGaAs photodetector having an avalanche photodiode (APD), a p-intrinsic-n (PIN) photodiode, and a microlens structure for focusing light on the APD. The method comprises the steps of providing an epitaxial structure having a substrate and a plurality of epitaxial layers formed thereon; forming a p-intrinsic-n (PIN) photodiode in the epitaxial structure; forming an avalanche photodiode (APD) in the epitaxial structure; forming a common cathode for the PIN photodiode and the APD; forming anode connections for the PIN photodiode and the APD; and forming a means for focusing light onto the APD on a back surface of the substrate.

### BRIEF DESCRIPTION OF THE DRAWINGS

Other important objects and features of the invention will be apparent from the following Detailed Description of the Invention taken in connection with the accompanying drawings in which:

FIG. 1a is a view of a combined APD/PIN InGaAs photodetector according to the present invention; FIG. 1b is a view of another embodiment of the combined APD/PIN InGaAs photodetector of the present invention, wherein a floating guard ring is provided about the APD.

FIG. 2 is a cross-sectional view of the combined APD/PIN InGaAs photodetector of the present invention, taken along the line 2-2 of FIG. 1a.

FIGS. 3-12 are cross-sectional views showing the method of the present invention for forming a combined APD/PIN InGaAs photodetector.

FIG. 13 is a partial cross-sectional view showing a focal plane array including a plurality of photodetectors according to the present invention.

### DETAILED DESCRIPTION OF THE INVENTION

The present invention relates to an InGaAs photodetector having an avalanche photodiode (APD) and a p-intrinsic-n (PIN) photodiode, wherein high (e.g., 100%) optical fill factors are provided for both the APD and the PIN photodiode. The photodetector can be used for both ranging and imaging applications, can be formed as a single pixel, and multiple pixels can be fabricated to form a focal plane array. The present invention also provides a method of manufacturing such a photodiode.

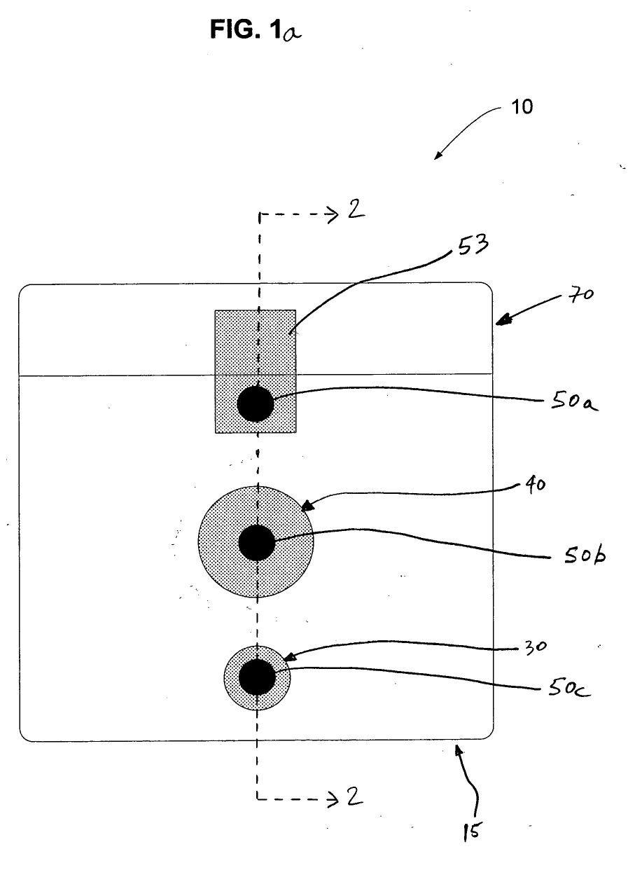

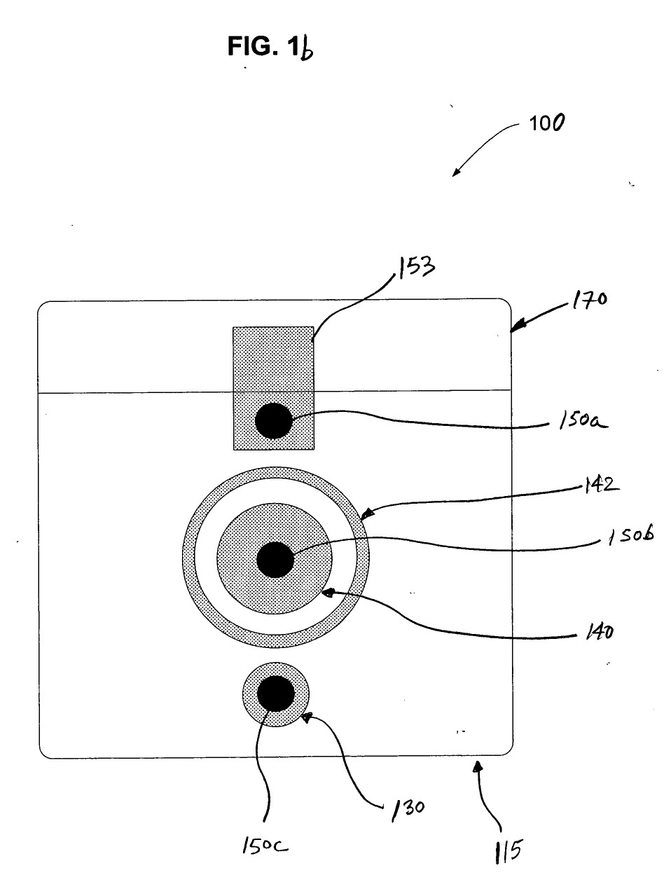

FIG. 1a is a view of an InGaAs photodetector according to the present invention, indicated generally at 10. The photodetector 10 includes an InGaAs wafer 15, in which is formed a p-intrinsic-n (PIN) type photodiode 30 and an avalance photodiode (APD) 40. The APD 40 is formed in a central region of the photodetector 10. The PIN photodiode 30 could be formed in any desired geometry and positioned at any desired location in the InGaAs wafer 15 outside of the central region occupied by the APD 40. A channel 70 is provided along an edge of the photodetector 10, and includes an N-type contact 50a that is common to both the PIN photodetector 30 and the APD 30. An interconnect 53 connects the N-type contact 50a to the substrate of the wafer 15. P-type contacts 50b and 50c are provided on the APD and PIN photodiodes 30 and 40, respectively, and allow for independent biasing of these components. Although the photodetector 10 is formed of InGaAs, other suitable materials are conceivable.

The photodetector 10 comprises a unit cell or pixel that is capable of detecting both ranges and intensities at the pixel level. Thus, the photodetector 10 is equally suited for ranging and imaging applications. Further, multiple photodetectors 10 could be provided and arranged to form a photodiode array of any desired resolution (e.g., 256×256 pixels), and the photodiode array could be connected to and operated by a suitable read-out integrated circuit (ROIC), forming a focal plane array. As will be discussed later in greater detail, the photodetector 10 includes a microlens structure and operates with a high (near 100%) optical fill factor during operation of either the PIN photodiode 30 or the APD 40, and across the entire optical space of the photodetector 10.

FIG. 1b is a view of another embodiment of the InGaAs photodetector of the present invention, indicated generally at 100, wherein a floating guard ring 142 is provided for controlling operation of the APD 140. As with the embodiment shown in FIG. 1a, the PIN photodiode 130 could be provided in any desired geometry and could be positioned at any desired location in the wafer 115, external to the guard ring 142. The channel 170 is provided along an edge of the detector 100. A common N-type contact 150a is provided, and is interconnected with the substrate of the wafer 115 by interconnect 153. The P-type contacts 150b and 150c allow for independent biasing of the APD 140 and PIN photodiode 130, respectively. The guard ring 142 “floats” in the sense that it is not in electrical communication with any part of the detector 100.

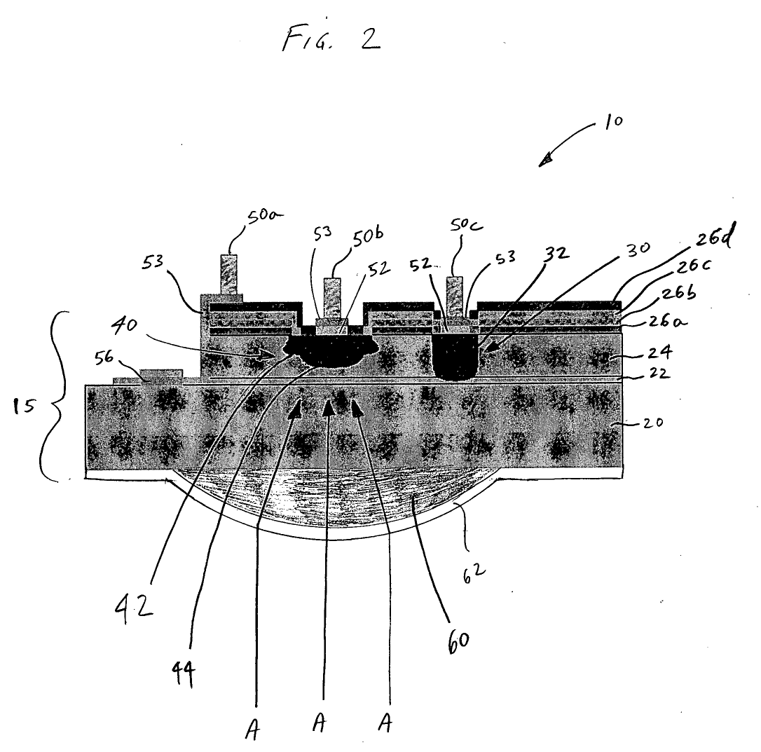

FIG. 2 is a cross-sectional view of the InGaAs photodetector 10 of the present invention, taken along the line 2-2 of FIG. 1a. The photodetector 10 is fabricated from a plurality of epitaxial layers (wafer) 15 including indium phosphide (InP) substrate 20, indium gallium arsenide (InGaAs) active layer 22, i-InP cap layer 24, and a plurality of silicon nitride passivation layers 26a-26d. PIN photodiode 30 is formed from a p-type zinc diffusion region 32 formed through i-InP cap layer 24 and into InGaAs active layer 22. APD 40 comprises an outer diffusion region 42 formed by diffusion of p-type zinc into i-InP cap layer 24, and active region 44 formed by diffusion of p-type zinc into i-InP cap layer 24 to a pre-defined depth chosen to optimize performance of the APD 40. Indium bump contacts 50a-50c provide electrical contacts for the photodetector 10, wherein contact 50a provides a common cathode for the photodetector 10, contact 50b provides an anode connection to the APD 40, and contact 50c provides an anode connection to the PIN photodiode 30. Contact 50a is connected to InP substrate 20 by metal interconnect 53 and ohmic n-type metal 56 at the channel 70. Contacts 50b and 50c are connected to the APD 40 and the PIN photodiode 30, respectively, by metal interconnect 53 and p-type ohmic metals 52.

A microlens structure 60 is provided on the substrate 20. The microlens structure 60 focuses incident light, indicated illustratively in FIG. 2 as light rays A, onto the APD 40 to achieve a high (e.g., 100 percent) optical fill factor for the APD 40. Thus, when the APD 40 is reverse-biased for operation (activated), the APD 40 operates with very high efficiency. When the APD 40 is deactivated by opening the bias connection to the APD (open-circuiting the APD), the PIN photodiode 30 can also be operated with high efficiency (nearly 100 percent fill factor), because charge carriers formed in the InGaAs active layer 22 diffuse toward the PIN photodiode 30 when the PIN photodiode 30 is operated. Thus, as can readily be appreciated, both the PIN photodiode 30 and the APD 40 can be operated with very high efficiency, thereby providing a photodetector 10 that is suitable for use in both ranging and imaging applications, as well as for data transmission and beam tracking. An antireflective coating 62 can be provided on the microlens structure 60 and the substrate 20.

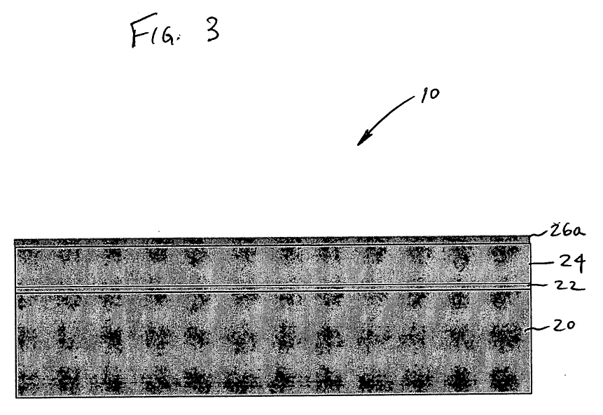

FIGS. 3-12 are cross-sectional views showing a method for forming the photodetector 10 of the present invention. The fabrication steps disclosed herein can be achieved using any suitable machinery and semiconductor fabrication techniques known in the art, and although specific types of epitaxial materials are utilized, it is to be understood that equivalents thereof which are known in the art can be substituted therefor without departing from the spirit or scope of the present invention. For example, the photodetector of the present invention can be formed using a silicon fabrication process, or other similar process. Further, a wafer containing multiple photodetectors can be formed using the processing steps disclosed herein, to mass-produce any desired quantity of photodetectors, a focal plane array, or other similar device.

Beginning in FIG. 3, a multi-layer epitaxial structure is provided including InP substrate 20, InGaAs active layer 22, i-InP cap layer 24, and silicon nitride (SiNx) layer 26a. SiNx layer 26a is deposited on top of i-InP cap layer 24 to minimize surface state density. Each of the layers 20, 22, 24, and 26a can be formed in a sequential deposition process, or alternatively, a pre-fabricated, multi-layer epitaxial structure that includes such layers can be utilized as a starting point for fabrication.

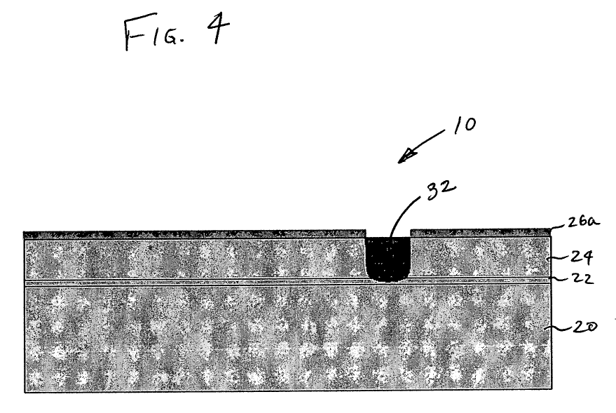

As shown in FIG. 4, an opening is formed in the SiNx layer 26a, and p-type zinc is diffused through the annular opening and into p-type zinc diffusion area 32 which extends through the i-InP cap layer 24 and into InGaAs active layer 22, forming the PIN photodiode 30.

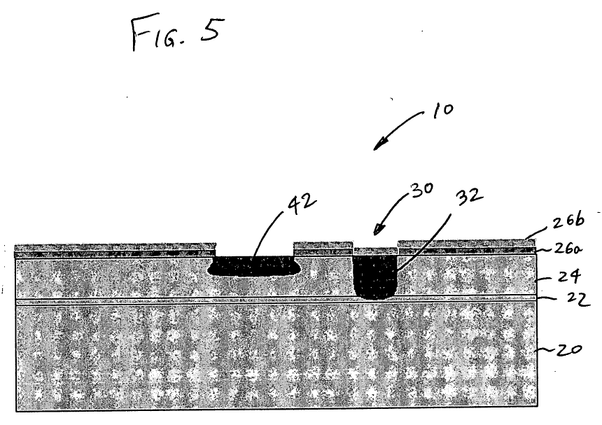

The next fabrication step is shown in FIG. 5, wherein another SiNx layer 26b is deposited over the first SiNx layer 26a and the p-type zinc diffusion area 32 formed in the previous step. Then, a hole is opened in the SiNx layer 26b corresponding to the outer region 42 of the APD 40. Zinc is diffused through the hole in the SiNx layer 26b and into the i-InP cap layer 24 to form the outer region 42.

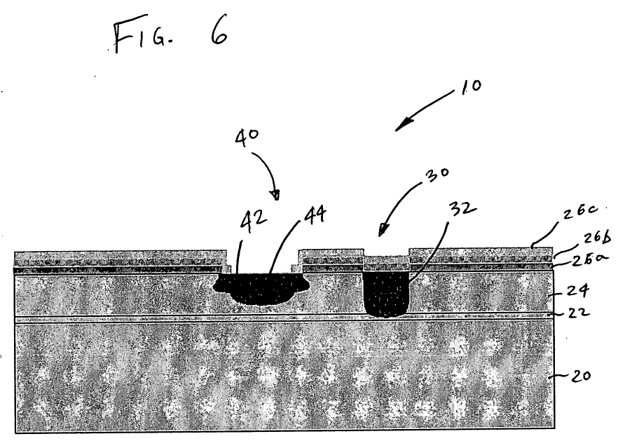

As shown in FIG. 6, another SiNx layer 26c is then deposited on the SiNx layer 26b, covering the outer region 42 formed in the previous steps. A hole is then formed in the SiNx layer 26c to expose a portion of the outer region 42, the hole having an area corresponding to a desired active region for the APD 40. P-type zinc is then diffused through the hole of the SiNx layer 26c and a portion of the outer region 42, and into the i-InP cap layer 24, to form active region 44. The active region 44 is preferably diffused to a depth sufficiently close to the InGaAs active layer 22 to provide optimum sensitivity for the APD 40. Together, the outer region 42 and active region 44 form the APD 40.

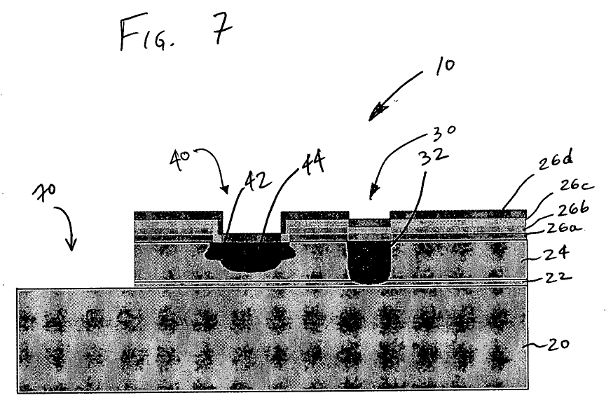

The next fabrication step is shown in FIG. 7, wherein a final layer of SiNx 26d is deposited on the SiNx layer 26c, covering the PIN photodiode 30 and the APD 40. A channel 70 is etched along an edge of the device for providing a common cathode, through SiNx layers 26a-26d, i-InP cap layer 24, and InGaAs active layer 22, exposing substrate 20. The channel 70 could be etched around the perimeter of a focal plane array containing the photodetector 10. For purposes of illustration only, the channel 70 is shown extending along only one side of the photodetector 10. Of course, the channel 70 could be etched completely around the perimeter of a single photodetector 10, or any combination thereof. Importantly, the channel 70 provides access to the substrate 20 so that a common cathode can be formed and shared across one or more APDs 40 or PIN photodiodes 30.

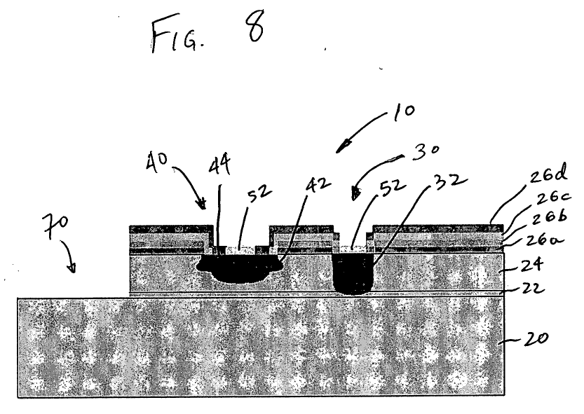

As shown in FIG. 8, once the channel 70 has been etched, a hole is opened in the SiNx layer 26d over the APD 40 and another hole is opened in the SiNx layers 26b-26d over the PIN photodiode 30 to expose portions of the diffused p-regions 32 and 42 of the PIN photodiode 30 and the APD 40. Then, p-type contact metal 52 is deposited in the holes, contacting portions of the diffused p-regions 32 and 42 of the PIN photodiode 30 and APD 40. The p-type contact metal 52 could be formed in these regions by a photo lift-off process, and annealed to form alloyed, ohmic contacts.

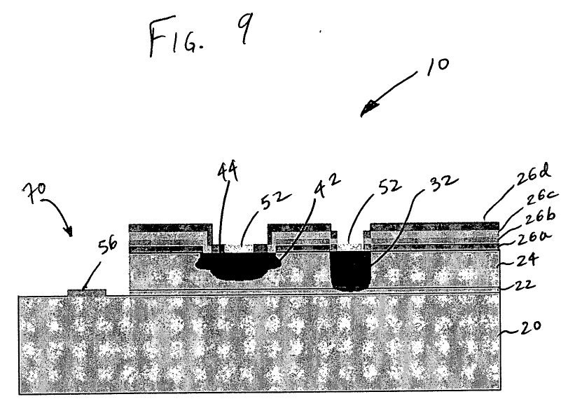

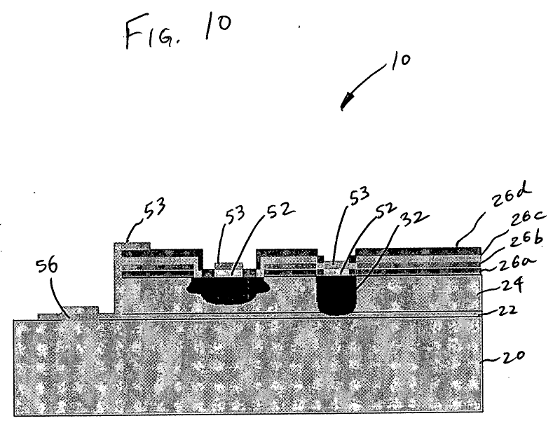

The next fabrication steps are shown in FIGS. 9-10, wherein a common cathode connection to the substrate 20 is formed. First, n-type contact metal 56 is deposited on the exposed substrate 20, as shown in FIG. 9. Then, as shown in FIG. 10, interconnects 53 are formed on top of the p-type contact metals 52, as well as on top of the n-type contact metal 56. The interconnect 53 formed on top of the n-type contact metal 56 is extended upward along the sides of layers 22, 24, and 26a-26d, and terminates on top of the layer 26d to form a common cathode for the photodetector 10. The interconnects 53 can be formed by a photo lift-off or any other suitable process. Importantly, the common cathode can be shared across a number of photodetectors 10, such as in a focal plane array. When the common cathode has been formed, global APD and PIN performance characteristics of the device can then be determined.

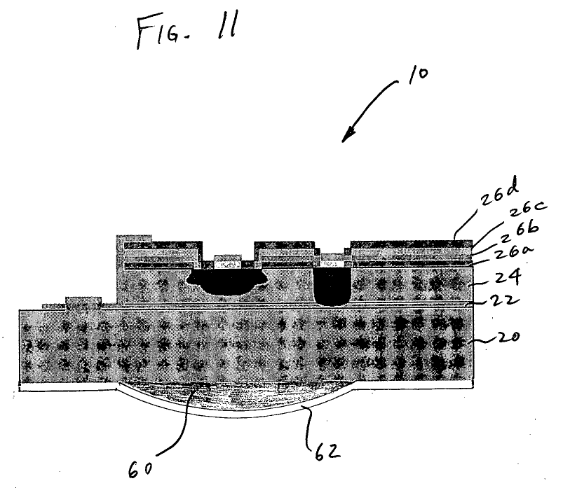

As shown in FIG. 11, once interconnects and contact metals have been formed, the substrate 20 is polished to a mirror finish and a microlens structure 60 is formed thereon. The microlens structure 60 can be formed according to any known process, such as a photoresist ion milling process. The microlens structure 60 could be formed form the same material as the substrate 20, such as indium phosphide (InP) or other suitable material. Further, the microlens structure 60 could be formed by etching the substrate 20 to form cylinders where lenses are required, and then heating to form the cylinders into a hemispherical shape. The microlens structure 60 and the substrate 20 are then coated with an anti-reflective coating 62 to maximize quantum efficiency.

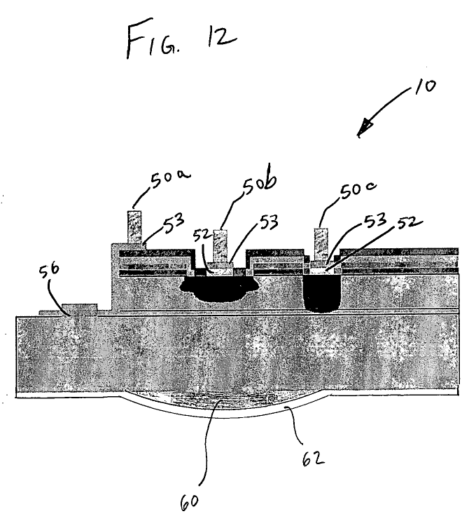

The final fabrication step is shown in FIG. 12, wherein indium bump contacts 50a, 50b, and 50c are formed on the interconnects 53. Contact 50a provides a common cathode connection for the photodetector 10. Contact 50b provides an anode connection for the APD 40. Contact 50c provides an anode connection for the PIN photodiode 30. The contacts 50 can be utilized to mate the photodetector 10 with a suitable read-out integrated circuit (ROIC), or to otherwise provide electrical connection points for the photodetector 10. Once the bump contacts 50a-50c have been formed, a wafer containing multiple photodetectors 10 can be diced into chips and prepared for hybridization to a ROIC.

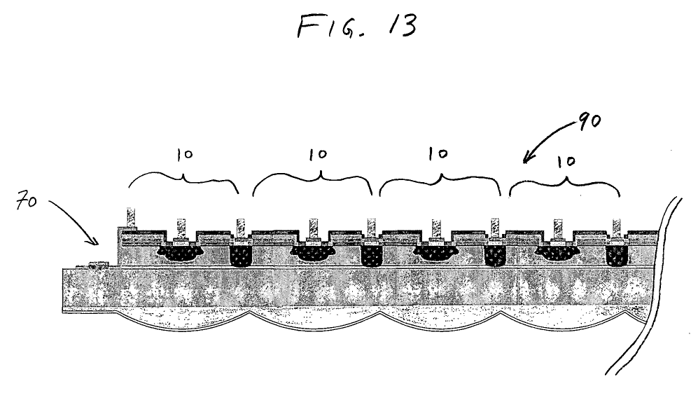

FIG. 13 is a partial cross-sectional view showing a focal plane array 90, which includes a plurality of photodetectors 10 according to the present invention. Each of the photodetectors 10 include a PIN photodiode, an APD, and a microlens structure for providing high (e.g., 100 percent) fill factor for the photodetector. The channel 70 provides a common cathode connection, and could be formed around the perimeter of the focal plane array 100. Each of the photodetectors 10 can be independently biased, and can perform ranging and imaging operations at the pixel level. Any desired number of photodetectors 10 can be provided to form a multi-pixel array, such as an array having 256×256 pixels of resolution.

Having thus described the invention in detail, it is to be understood that the foregoing description is not intended to limit the spirit and scope thereof. What is desired to be protected by Letters Patent is set forth in the appended claims.

What is claimed is:

1. An InGaAs photodetector comprising:
an epitaxial structure including a substrate with epitaxial layers formed thereon;
an avalanche photodiode (APD) formed in the epitaxial structure;
a p-intrinsic-n (PIN) photodiode formed in the epitaxial structure; and
means on the substrate for focusing light onto the APD and providing high optical fill factors for the APD and the PIN photodiode.

2. The photodetector of claim 1, further comprising a floating guard ring formed in the epitaxial structure and surrounding the APD.

3. The photodetector of claim 1, further comprising a common cathode connected to the APD and the PIN photodiode.

4. The photodetector of claim 3, wherein the APD and the PIN photodiode can be independently biased using the common cathode and anodes of the APD and the PIN photodiode.

5. The photodetector of claim 1, wherein the means on the substrate for focusing light on the APD comprises a microlens structure formed on the substrate for focusing light on the APD.

6. The photodetector of claim 1, wherein the epitaxial structure comprises an indium phosphide (InP) substrate, an indium gallium arsenide (InGaAs) active layer, an InP cap layer, and a plurality of silicon nitride (SiNx) layers.

7. An InGaAs focal plane array comprising:
an epitaxial structure including a substrate with epitaxial layers formed thereon;
a plurality of photodetectors formed in the epitaxial structure, each of the plurality photodetectors including an avalanche photodiode (APD) and a p-intrinsic-n (PIN) photodiode;
a common cathode connected to each of the plurality of photodetectors; and
a plurality of microlenses formed on the substrate for focusing light onto the APDs of the plurality of photodetectors and providing high optical fill factors for the plurality of photodetectors.

8. The focal plane array of claim 7, wherein the APD and PIN photodetectors of each of the plurality of photodetectors are independently biased.

9. The focal plane array of claim 8, wherein the common cathode is formed about the perimeter of the focal plane array.

10. A method of fabricating an InGaAs photodetector comprising:
providing an epitaxial structure having a substrate and a plurality of epitaxial layers formed thereon;
forming a p-intrinsic-n (PIN) photodiode in the epitaxial structure;
forming an avalanche photodiode (APD) in the epitaxial structure;
forming a common cathode for the PIN photodiode and the APD;
forming anode connections for the PIN photodiode and the APD; and
forming a means for focusing light onto the APD on a back surface of the substrate.

11. The method of claim 10, wherein the step of providing the epitaxial structure comprises providing a multi-layer epitaxial structure having an indium phosphide (InP) substrate layer, an indium gallium arsenide (InGaAs) active layer, an InP cap layer, and a first silicon nitride (SiNx) layer.

12. The method of claim 11, wherein the step of forming the PIN photodiode comprises:
opening a hole in the first SiNx layer corresponding to the PIN photodiode; and
diffusing p-type zinc through the hole and into the InP cap layer and InGaAs active layer.

13. The method of claim 12, wherein the step of forming the APD comprises:
depositing an second SiNx layer over the first SiNx layer;
opening a hole in the second SiNx layer corresponding to an outer region of the APD; and
diffusing p-type zinc through the hole and into the i-InP cap layer to form the outer region of the APD.

14. The method of claim 13, wherein the step of forming the APD comprises:
depositing a third SiNx layer over the second SiNx layer;
opening a hole in the third SiNx layer corresponding to an active region of the APD; and
diffusing p-type zinc through the hole and into the i-InP cap layer to form the active region of the APD.

15. The method of claim 14, wherein the step of forming the common cathode comprises:
depositing a fourth SiNx layer over the third SiNx layer;
etching a channel along at least one edge of the photodetector, said channel extending through the SiNx layers, the InP cap layer, and the InGaAs active layer and exposing a portion of the substrate;
depositing an N-type contact metal on an exposed portion of the substrate; and
forming an interconnect connected at one end to the N-type contact metal, extending upward, and terminating at a second end on top of the fourth SiNx layer.

16. The method of claim 15, wherein the step of forming anode connections for the APD and the PIN photodiodes comprises:
opening a first hole in the fourth SiNx layer corresponding to a first anode contact for the APD;
opening a second hole in the fourth SiNx layer corresponding to a second anode contact for the PIN photodiode; and
depositing p-type contact metal in the first and second holes, said p-type contact metal contacting p-diffused regions of the APD and PIN photodiodes.

17. The method of claim 10, wherein the step of forming the means for focusing light comprises polishing the substrate and forming a microlens structure on the substrate.

18. The method of claim 17, further comprising applying an anti-reflective coating to the microlens structure.

19. The method of claim 10, further comprising forming indium bump contacts on the common cathode and the anode connections.

20. The method of claim 19, further comprising dicing the photodetector from a wafer an hybridizing the photodetector with a read-out integrated circuit (ROIC) for operation.

21. A photodetection method comprising the steps of:
providing a photodetector having a p-intrinsic-n (PIN) photodiode, an avalanche photodiode (APD), and a microlens structure for focusing light on the APD;
activating the APD;
detecting light focused on the APD by the microlens structure;
deactivating the APD; and
detecting light using the PIN photodiode.

22. The method of claim 21, wherein the step of activating the APD comprises reverse biasing the APD.

23. The method of claim 21, wherein the step of deactivating the APD comprises open-circuiting the APD.

24. The method of claim 21, wherein the step of detecting light using the PIN photodiode comprises open-circuiting the APD and allowing charge carriers generated in the photodetector in response to the light to diffuse to the PIN photodiode to provide a high optical fill factor for the PIN photodiode.
